(19) United States
(12) Patent Application Publication
(10) Pub. No.: US 2026/0020474 A1
(43) Pub. Date: Jan. 15, 2026

(54) DISPLAY DEVICE AND ELECTRONIC DEVICE INCLUDING THE SAME

(71) Applicant: Samsung Display Co., Ltd., Yongin-si, Gyeonggi-do (KR)

(72) Inventors: TAE-CHANG KIM, Yongin-si (KR); JIHEON LEE, Yongin-si (KR); HAEJIN KIM, Yongin-si (KR)

(21) Appl. No.: 19/229,892

(22) Filed: Jun. 5, 2025

(30) Foreign Application Priority Data
Jul. 9, 2024 (KR) 10-2024-0090199

(51) Int. Cl. H10K 59/80; G06F 1/16; H10K 59/40; H10K 102/00

(52) U.S. Cl. CPC H10K 59/871; G06F 1/1616; G06F 1/1643; G06F 1/1656; H10K 59/40; H10K 2102/311

(57) ABSTRACT

A display device includes: a display module; a support plate under the display module and comprising a first support plate, a second support plate, and a folding plate between the first and second support plates, the folding plate being provided with openings defined therethrough and the first support plate, the second support plate, and the folding plate being arranged in a first direction; a first wing plate under the folding plate; a second wing plate under the folding plate and spaced apart from the first wing plate in the first direction; a center plate between the first and second wing plates; a folding supporter between the center plate and the folding plate; and a cover layer between the folding supporter and the folding plate.

### CROSS-REFERENCE TO RELATED APPLICATION

The present application claims priority to and the benefit of Korean Patent Application No. 10-2024-0090199, filed on Jul. 9, 2024, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of Related Art

Electronic devices that provide images to users, such as smart phones, digital cameras, notebook computers, navigation units, and smart televisions, include a display device to display the images. A display device generates the images and provides the images to users through a display screen thereof.

In recent years, with the technological development of display devices, various types of display devices are being developed. For example, various flexible display devices, which are foldable, rollable, or capable of being transformed into a curved shape, are being developed. The flexible display devices are easy to carry and improve a user's convenience.

Among the flexible display devices, a folding display device includes a display module that may be folded with respect to a folding axis extending in one direction without damaging the display device. The display module is folded or unfolded with respect to the folding axis. The display module includes a folding area folded during a folding operation thereof. The folding area is folded to have a radius of curvature (e.g., a set or predetermined radius of curvature). When the display module is repeatedly folded and unfolded, a portion of the folding area, which overlaps the folding axis, may be deformed, and the deformed portion may be visible to users as a crease.

The above information disclosed in this Background section is only for enhancement of understanding of the background and therefore the information discussed in this Background section does not necessarily constitute prior art.

### SUMMARY

Aspects of some embodiments of the present disclosure include a display device that may be capable of preventing or reducing a crease in a folding area of a display module and an electronic device including the same.

Aspects of some embodiments of the present disclosure include a display device including a display module, a support plate under the display module and including a first support plate, a second support plate, and a folding plate between the first and second support plates, a first wing plate under the folding plate, a second wing plate under the folding plate and spaced apart from the first wing plate in a first direction, a center plate between the first and second wing plates, a folding supporter between the center plate and the folding plate, and a cover layer between the folding supporter and the folding plate. According to some embodiments, the folding plate is provided with openings defined therethrough, and the first support plate, the second support plate, and the folding plate are arranged in the first direction.

According to some embodiments, the folding supporter overlaps the openings in a plan view.

According to some embodiments, the cover layer covers the openings.

According to some embodiments, the folding supporter has a width smaller than a width of the cover layer in the first direction.

According to some embodiments, the folding supporter overlaps a center of the cover layer.

According to some embodiments, an upper surface of the folding supporter is higher than lower ends of both sides of the cover layer, and a portion of the cover layer, which overlaps the folding supporter, protrudes upward by a predetermined height due to the folding supporter.

According to some embodiments, a distance between an upper end of both sides of the cover layer, which are opposite to each other in the first direction, and an uppermost end of an upper surface of the cover layer is within a range from 0 micrometers to 50 micrometers.

According to some embodiments, the folding supporter is in contact with a lower surface of the cover layer.

According to some embodiments, the display device further includes a first single-sided tape attached to an upper surface of the first wing plate and a second single-sided tape attached to an upper surface of the second wing plate.

According to some embodiments, the display device further includes a center single-sided tape attached to an upper surface of the center plate.

According to some embodiments, the folding supporter is on the center single-sided tape.

According to some embodiments, the folding supporter is attached to the center single-sided tape.

According to some embodiments, the folding plate includes a curved portion through which the openings are defined, a first reverse curvature portion between the first support plate and the curved portion, a second reverse curvature portion between the second support plate and the curved portion, a first extension portion between the curved portion and the first reverse curvature portion, and a second extension portion between the curved portion and the second reverse curvature portion, the first wing plate is under the first extension portion, the second wing plate is under the second extension portion, and the center plate is under the curved portion.

According to some embodiments, the display device further includes a first flat plate under the first support plate and a second flat plate under the second support plate.

According to some embodiments, the display device further includes a metal sheet between the folding plate and the first and second wing plates and between the center plate and the folding plate.

According to some embodiments, the display device further includes a plurality of dummy folding supporters between the folding plate and the first and second wing plates.

Aspects of some embodiments of the present disclosure include a display device including a display module, a support plate under the display module and including a first support plate, a second support plate, and a folding plate between the first and second support plates, a first wing plate under the folding plate, a second wing plate under the folding plate and spaced apart from the first wing plate in a first direction, a first folding supporter between the first wing plate and the folding plate, and a second folding supporter between the second wing plate and the folding plate. According to some embodiments, the folding plate is provided with openings defined therethrough, and the first support plate, the second support plate, and the folding plate are arranged in the first direction.

According to some embodiments, the display device further includes a digitizer between the support plate and the first and second folding supporters.

According to some embodiments, the display device further includes a metal sheet between the first and second wing plates and the first and second folding supporters.

According to some embodiments, the display device further includes a first single-sided tape attached to an upper surface of the first wing plate and a second single-sided tape attached to an upper surface of the second wing plate. According to some embodiments, the first folding supporter is on the first single-sided tape, and the second folding supporter is on the second single-sided tape.

Aspects of some embodiments of the present disclosure include an electronic device including a display device for providing an image. According to some embodiments, the display device includes a display module, a support plate under the display module and including a first support plate, a second support plate, and a folding plate between the first and second support plates, a first wing plate under the folding plate, a second wing plate under the folding plate and spaced apart from the first wing plate in a first direction, a center plate between the first and second wing plates, a folding supporter between the center plate and the folding plate, and a cover layer between the folding supporter and the folding plate. According to some embodiments, the folding plate is provided with openings defined therethrough, and the first support plate, the second support plate, and the folding plate are arranged in the first direction.

### BRIEF DESCRIPTION OF THE DRAWINGS

The above and other aspects of embodiments according to the present disclosure will become more readily apparent by reference to the following detailed description when considered in conjunction with the accompanying drawings wherein:

FIG. 1 is a perspective view of a display device according to some embodiments of the present disclosure;

FIG. 2 is a perspective view of a folded state of the display device shown in FIG. 1;

FIG. 3 is a cross-sectional view of a display module according to some embodiments of the present disclosure;

FIG. 4 is a cross-sectional view of a display panel shown in FIG. 3;

FIG. 5 is a plan view of a display device shown in FIG. 1;

FIG. 6 is a cross-sectional view of a display device taken along a line I-I′ of FIG. 5 according to some embodiments of the present disclosure;

FIG. 7 is a perspective view of a support plate shown in FIG. 6;

FIG. 8 is an enlarged plan view of an area AA shown in FIG. 7;

FIG. 9 is a view of a display device shown in FIG. 6;

FIG. 10 is a view of a folded state of the display device shown in FIG. 9;

FIG. 11 is a cross-sectional view of a folding plate and a folding area of a comparative display device in a state in which the comparative display device has been repeatedly folded and unfolded according to a comparative embodiment;

FIG. 12 is an enlarged view of a folding area shown in FIG. 9;

FIG. 13A is a photograph showing a folding test result of the comparative display device shown in FIG. 11;

FIG. 13B is a photograph showing a folding test result of the display device shown in FIG. 12;

FIG. 14 is a graph illustrating a deformation amount of a comparative display module and a display module according to folding test results of the comparative display device and the display device of the present disclosure; and

FIGS. 15 to 20 are cross-sectional views of display devices according to embodiments of the present disclosure.

FIG. 21 is a block diagram of an electronic device, according to some embodiments of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content.

As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, aspects of some embodiments of the present disclosure will be described in more detail with reference to accompanying drawings.

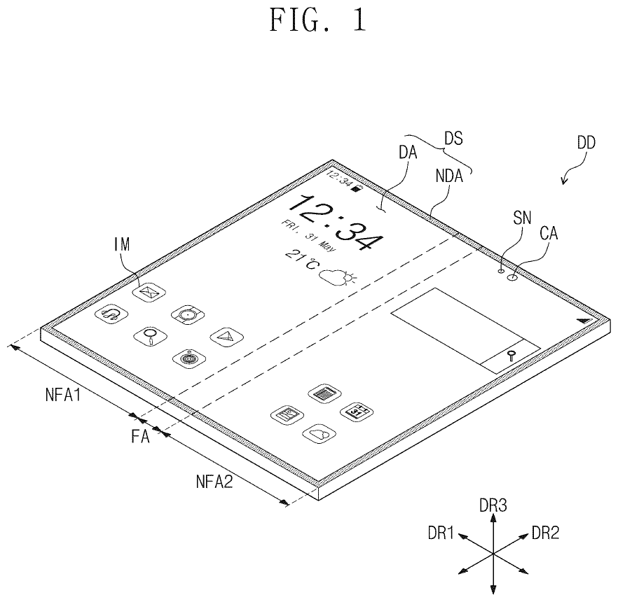

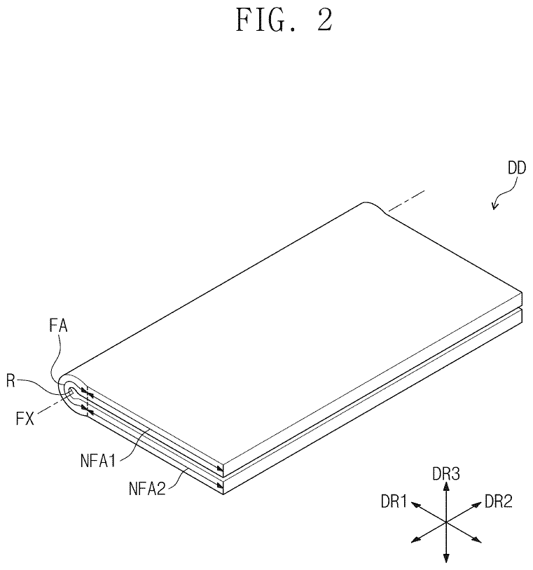

FIG. 1 is a perspective view of a display device DD according to some embodiments of the present disclosure. FIG. 2 is a perspective view of a folded state of the display device DD shown in FIG. 1.

Referring to FIG. 1, the display device DD may have a rectangular shape defined by short sides extending in a first direction DR1 and long sides extending in a second direction DR2 intersecting the first direction DR1. However, the shape of the display device DD should not be limited to the rectangular shape, and the display device DD may have various shapes, such as a circular shape and a polygonal shape. The display device DD may be a flexible display device.

Hereinafter, a direction perpendicular to a plane defined by the first direction DR1 and the second direction DR2 may be referred to as a third direction DR3. In the present disclosure, the expressions “when viewed in a plane” or “in a plan view” refer to a state of being viewed from the third direction DR3.

The display device DD may include a folding area FA and a plurality of non-folding areas NFA1 and NFA2. The non-folding areas NFA1 and NFA2 may include a first non-folding area NFA1 and a second non-folding area NFA2. The folding area FA may be located between the first non-folding area NFA1 and the second non-folding area NFA2. The first non-folding area NFA1, the folding area FA, and the second non-folding area NFA2 may be arranged in the first direction DR1.

According to some embodiments, one folding area FA and two non-folding areas NFA1 and NFA2 are shown as a representative example, however, the number of the folding areas FA and the number of non-folding areas NFA1 and NFA2 should not be limited thereto or thereby. As an example, the display device DD may include more than two non-folding areas and a plurality of folding areas located between the non-folding areas.

An upper surface of the display device DD may be referred to as a display surface DS, and the display surface DS may be a plane defined by the first direction DR1 and the second direction DR2. Images IM generated by the display device DD may be provided to a user through the display surface DS.

The display surface DS may include a display area DA and a non-display area NDA around the display area DA. The display area DA may display the image, and the non-display area NDA may not display the image. The non-display area NDA may surround the display area DA and may define an edge of the display device DD, which is printed by a color (e.g., a set or predetermined color).

The display device DD may include at least one sensor SN and at least one camera CA. The sensor SN and the camera CA may be located adjacent to the edge of the display device DD. The sensor SN and the camera CA may be located in the display area DA adjacent to the non-display area NDA. The sensor SN and the camera CA may be located in the second non-folding area NFA2, however, according to some embodiments, the sensor SN and the camera CA may be located in the first non-folding area NFA1.

A light may be provided to the camera CA and the sensor SN after passing through portions of the display device DD in which the sensor SN and the camera CA are located. As an example, the sensor SN may be a proximity illumination sensor, however, the sensor SN should not be particularly limited. The camera CA may take a picture of external objects. Each of the sensor SN and the camera CA may be provided in plural.

Referring to FIG. 2, the display device DD may be a foldable display device DD that is folded or unfolded. The folding area FA may be folded with respect to a folding axis FX parallel (or substantially parallel) to the second direction DR2, and thus, the display device DD may be folded. The folding axis FX may be defined as a major axis parallel (or substantially parallel) to the long sides of the display device DD, however, embodiments according to the present disclosure are not limited thereto or thereby. According to some embodiments, the folding axis FX may be defined as a minor axis parallel (or substantially parallel) to the short sides of the display device DD, and the display device DD may be folded with respect to a folding axis parallel (or substantially parallel) to the short side of the display device DD.

When the display device DD is folded, the display device DD may be inwardly folded (in-folding) such that the first non-folding area NFA1 and the second non-folding area NFA2 may face each other and the display surface DS may not be exposed to the outside. However, embodiments according to the present disclosure re not limited thereto or thereby. As an example, the display device DD may be outwardly folded (out-folding) with respect to the folding axis FX such that the display surface DS may be exposed to the outside.

A distance between the first non-folding area NFA1 and the second non-folding area NFA2 may be smaller than a diameter of a circle defined by a radius of curvature R of the folding area FA. Accordingly, the folding area FA may be folded to have a dumbbell shape, and thus, the distance between the first non-folding area NFA1 and the second non-folding area NFA2 may be reduced.

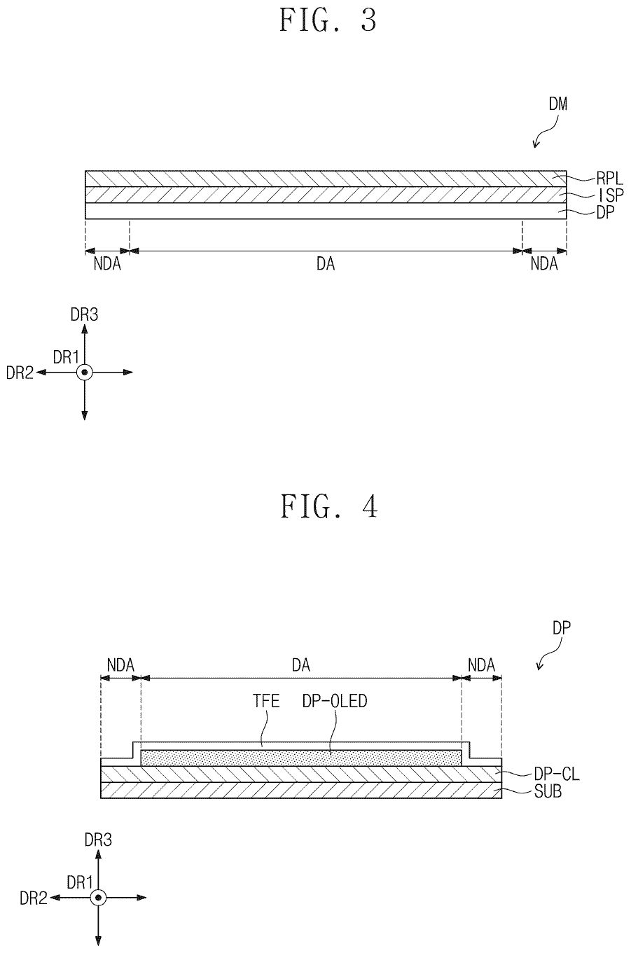

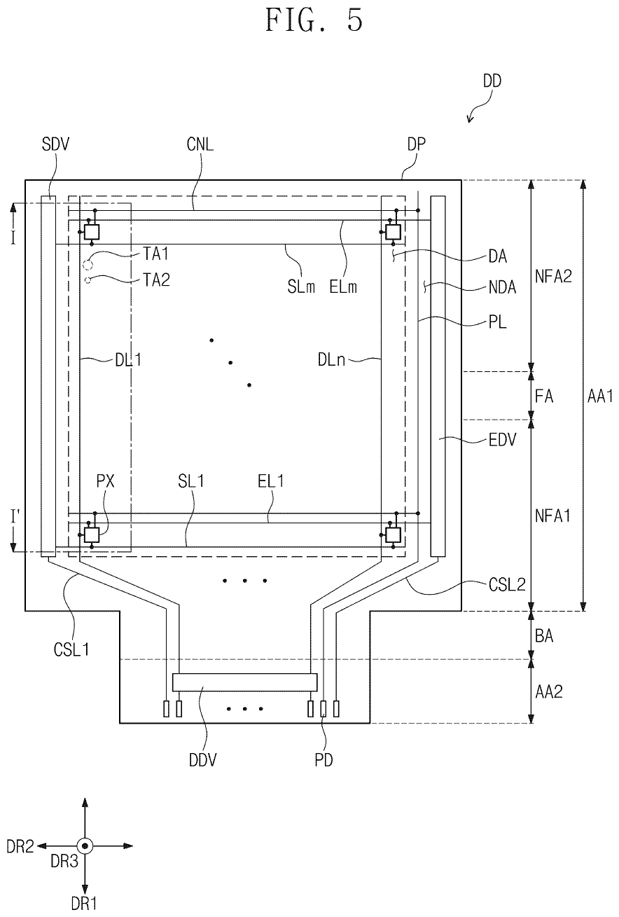

FIG. 3 is a cross-sectional view of a display module DM according to some embodiments of the present disclosure, and FIG. 4 is a cross-sectional view of a display panel DP shown in FIG. 3.

FIGS. 3 and 4 respectively show the cross-sections of the display module DM and the display panel DP when viewed in the first direction DR1.

Referring to FIG. 3, the display module DM may include the display panel DP, an input sensing part ISP located on the display panel DP, and an anti-reflective layer RPL located on the input sensing part ISP. The display device DD may include the display module DM.

The display panel DP may be a flexible display panel. According to some embodiments, the display panel DP may be a light emitting type display panel, however, it should not be particularly limited. As an example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as a representative example of the display panel DP.

The input sensing part ISP may include a plurality of sensors to sense an external input by a capacitive method. The input sensing part ISP may be manufactured directly on the display panel DP when the display device DD is manufactured, however, it should not be limited thereto or thereby. According to some embodiments, the input sensing part ISP may be attached to the display panel DP by an adhesive layer after being manufactured separately from the display panel DP.

The anti-reflective layer RPL may be formed directly on the input sensing part ISP when the display device DD is manufactured, however, it should not be limited thereto or thereby. According to some embodiments, the anti-reflective layer RPL may be attached to the input sensing part ISP by an adhesive layer after being manufactured separately.

The anti-reflective layer RPL may be defined as an external light reflection prevention film. The anti-reflective layer RPL may decrease a reflectance of an external light incident to the display panel DP from the above of the display device DD.

Referring to FIG. 4, the display panel DP may include a substrate SUB, a circuit element layer DP-CL located on the substrate SUB, a display element layer DP-OLED located on the circuit element layer DP-CL, and a thin film encapsulation layer TFE located on the display element layer DP-OLED.

The substrate SUB may include the display area DA and the non-display area NDA around the display area DA. The substrate SUB may include glass or a flexible plastic material, e.g., polyimide (PI). The display element layer DP-OLED may be located in the display area DA.

A plurality of pixels may be located in the circuit element layer DP-CL and the display element layer DP-OLED. Each of the pixels may include a transistor located in the circuit element layer DP-CL and a light emitting element located in the display element layer DP-OLED and connected to the transistor.

The thin film encapsulation layer TFE may be located on the circuit element layer DP-CL to cover the display element layer DP-OLED. The thin film encapsulation layer TFE may protect the pixels from moisture, oxygen, and foreign substances.

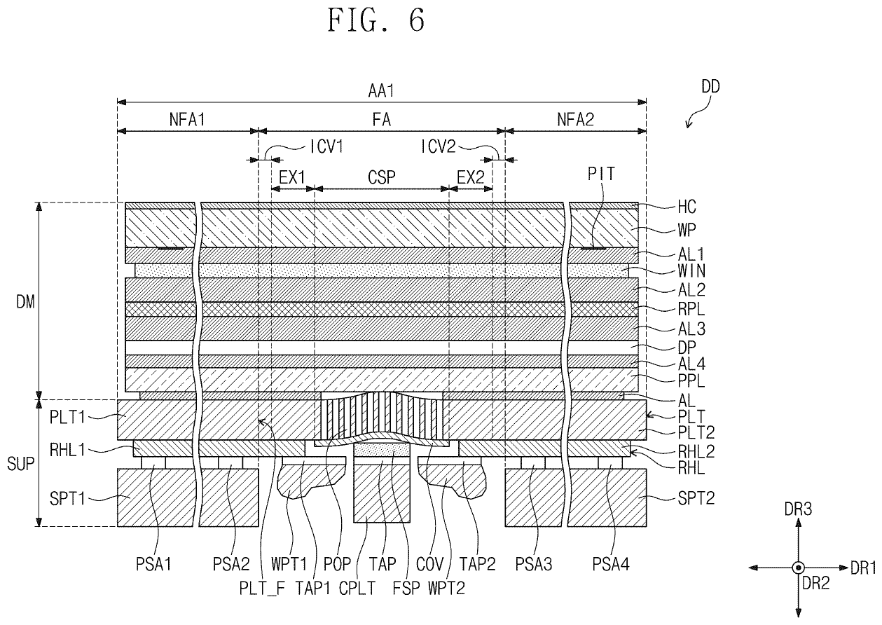

FIG. 5 is a plan view of the display device shown in FIG. 1.

Referring to FIG. 5, the display device DD may include the display panel DP, a scan driver SDV, the data driver DDV, and an emission driver EDV.

The display panel DP may include a first area AA1, a second area AA2, and a bending area BA between the first area AA1 and the second area AA2. The bending area BA may extend in the second direction DR2, and the first area AA1, the bending area BA, and the second area AA2 may be arranged in the first direction DR1.

The first area AA1 may include the display area DA and the non-display area NDA around the display area DA. The non-display area NDA may surround the display area DA. The display area DA may be an area in which the image is displayed, and the non-display area NDA may be an area in which the image is not displayed. The second area AA2 and the bending area BA may be areas in which the image is not displayed.

When viewed in the second direction DR2, the first area AA1 may include the first non-folding area NFA1, the second non-folding area NFA2, and the folding area FA between the first non-folding area NFA1 and the second non-folding area NFA2. The first and second non-folding areas NFA1 and NFA2 and the folding area FA may respectively correspond to the first and second non-folding areas NFA1 and NFA2 and the folding area FA of the display device DD shown in FIG. 1. First and second transmission areas TA1 and TA2 may be defined in the display area DA and the second non-folding area NFA2. The camera CA and the sensor SN may be located in the first transmission area TA1 and the second transmission area TA2, respectively.

The first area AA1 may be folded with respect to the folding axis FX. As an example, as the folding area FA of the first area AA1 is folded with respect to the folding axis FX, the display panel DP may be folded.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connection lines CNL, and a plurality of pads PD. Each of m and n is a natural number. The pixels PX may be arranged in the display area DA and may be connected to the scan lines SL1 to SLm, the data lines DL1 to DLn, and the emission lines EL1 to ELm.

The scan driver SDV and the emission driver EDV may be located in the non-display area NDA. The scan driver SDV and the emission driver EDV may be located in the non-display area NDA to be respectively adjacent to both sides of the first area AA1, which are opposite to each other in the second direction DR2. The data driver DDV may be located in the second area AA2. The data driver DDV may be manufactured in an integrated circuit chip form and may be mounted on the second area AA2.

The scan lines SL1 to SLm may extend in the second direction DR2 and may be connected to the scan driver SDV. The data lines DL1 to DLn may extend in the first direction DR1 and may be connected to the data driver DDV via the bending area BA. The data driver DDV may be connected to the pixels PX through the data lines DL1 to DLn. The emission lines EL1 to ELm may extend in the second direction DR2 and may be connected to the emission driver EDV.

The power line PL may extend in the first direction DR1 and may be located in the non-display area NDA. The power line PL may be located between the display area DA and the emission driver EDV. The power line PL may extend to the second area AA2 via the bending area BA. When viewed in a plane (or in a plan view), the power line PL may extend to a lower end of the second area AA2. The power line PL may receive a driving voltage.

The connection lines CNL may extend in the second direction DR2 and may be arranged in the first direction DR1. The connection lines CNL may be connected to the power line PL and the pixels PX. The driving voltage may be applied to the pixels PX via the power line PL and the connection lines CNL connected to the power line PL.

The first control line CSL1 may be connected to the scan driver SDV and may extend toward the lower end of the second area AA2 via the bending area BA. The second control line CSL2 may be connected to the emission driver EDV and may extend toward the lower end of the second area AA2 via the bending area BA. The data driver DDV may be located between the first control line CSL1 and the second control line CSL2.

When viewed in the plane (or in a plan view), the pads PD may be located adjacent to the lower end of the second area AA2. The data driver DDV, the power line PL, the first control line CSL1, and the second control line CSL2 may be connected to the pads PD.

The data lines DL1 to DLn may be connected to corresponding pads PD via the data driver DDV. As an example, the data lines DL1 to DLn may be connected to the data driver DDV, and the data driver DDV may be connected to the pads PD corresponding to the data lines DL1 to DLn.

According to some embodiments, a printed circuit board may be connected to the pads PD, and a timing controller and a voltage generator may be located on the printed circuit board. The timing controller may be manufactured in an integrated circuit chip and may be mounted on the printed circuit board. The timing controller and the voltage generator may be connected to the pads PD via the printed circuit board.

The timing controller may control an operation of the scan driver SDV, the data driver DDV, and the emission driver EDV. The timing controller may generate a scan control signal, a data control signal, and an emission control signal in response to control signals applied thereto from the outside. The voltage generator may generate the driving voltage.

The scan control signal may be applied to the scan driver SDV via the first control line CSL1. The emission control signal may be applied to the emission driver EDV via the second control line CSL2. The data control signal may be applied to the data driver DDV. The timing controller may receive image signals from the outside, may convert a data format of the image signals to a data format appropriate to an interface between the timing controller and the data driver DDV, and may provide the converted image signals to the data driver DDV.

The scan driver SDV may generate a plurality of scan signals in response to the scan control signal. The scan signals may be applied to the pixels PX via the scan lines SL1 to SLm. The scan signals may be sequentially applied to the pixels PX.

The data driver DDV may generate a plurality of data voltages corresponding to the image signals in response to the data control signal. The data voltages may be applied to the pixels PX via the data lines DL1 to DLn. The emission driver EDV may generate a plurality of emission signals in response to the emission control signal. The emission signals may be applied to the pixels PX via the emission lines EL1 to ELm.

The pixels PX may receive the data voltages in response to the scan signals. The pixels PX may emit a light having a luminance corresponding to the data voltages in response to the emission signals, and thus, the image may be displayed. An emission time of the pixels PX may be controlled by the emission signals.

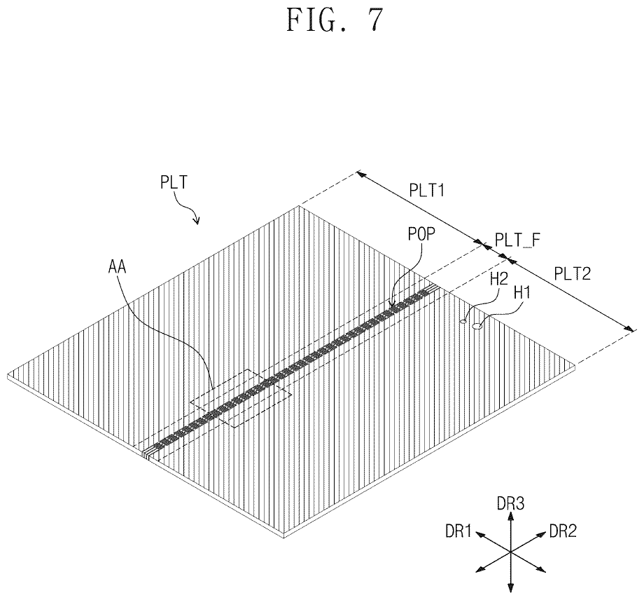

FIG. 6 is a cross-sectional view of the display device DD taken along a line I-I′ of FIG. 5 according to some embodiments of the present disclosure.

Referring to FIG. 6, the display device DD may include the display module DM, a supporter SUP located under the display module DM, and an adhesive layer AL located between the display module DM and the supporter SUP. The display module DM and the supporter SUP may be attached to each other by the adhesive layer AL.

The display module DM may be a flexible display module. The display module DM may include the first non-folding area NFA1, the folding area FA, and the second non-folding area NFA2 arranged in the first direction DR1, like the display panel DP. The supporter SUP located under the display module DM may support the display module DM.

Hereinafter, configurations of the display module DM and the supporter SUP will be described in detail based on the display device DD that is in a flat state.

The display module DM may include the display panel DP, the anti-reflective layer RPL, a window WIN, a window protective layer WP, a hard coating layer HC, a panel protective layer PPL, and first, second, third, and fourth adhesive layers AL1, AL2, AL3, and AL4. The anti-reflective layer RPL, the window WIN, the window protective layer WP, and the hard coating layer HC may be located above the display panel DP. The panel protective layer PPL may be located under the display panel DP.

The anti-reflective layer RPL may be located on the display panel DP. The anti-reflective layer RPL may be defined as an external light reflection prevention film. The anti-reflective layer RPL may decrease a reflectance with respect to an external light incident to the display panel DP from the above of the display device DD.

In a case where the external light incident to the display panel DP is provided to the user after being reflected by the display panel DP, like a mirror, the user may perceive the external light. The anti-reflective layer RPL may include color filters that display the same colors as those of the pixels to prevent or reduce the above-mentioned phenomenon.

The color filters may filter the external light such that the external light may have the same color as the pixels. In this case, the external light may not be perceived by the user. However, the present disclosure should not be limited thereto or thereby, and the anti-reflective layer RPL may include a retarder and/or a polarizer to reduce the reflectance with respect to the external light.

The window WIN may be located on the anti-reflective layer RPL. The window WIN may protect the display panel DP and the anti-reflective layer RPL from external scratches. The window WIN may have an optically transparent property. The window WIN may include a glass material, however, it should not be limited thereto or thereby. According to some embodiments, the window WIN may include a synthetic resin film.

The window WIN may have a single-layer or multi-layer structure. As an example, the window WIN may include a plurality of synthetic resin films attached to each other by an adhesive or a glass substrate and a synthetic resin film attached to the glass substrate by an adhesive.

The window protective layer WP may be located on the window WIN. The window protective layer WP may include the flexible plastic material, such as polyimide (PI) or polyethylene terephthalate (PET). The hard coating layer HC may be located on an upper surface of the window protective layer WP.

A print layer PIT may be located on a lower surface of the window protective layer WP. The print layer PIT may have a black color, however, a color of the print layer PIT should not be limited to the black color. The print layer PIT may be located adjacent to an edge of the window protective layer WP.

The first adhesive layer AL1 may be located between the window protective layer WP and the window WIN. The window protective layer WP may be attached to the window WIN by the first adhesive layer AL1. The first adhesive layer AL1 may be located under the window protective layer WP and may cover the print layer PIT.

The second adhesive layer AL2 may be located between the window WIN and the anti-reflective layer RPL. The window WIN may be attached to the anti-reflective layer RPL by the second adhesive layer AL2.

The third adhesive layer AL3 may be located between the anti-reflective layer RPL and the display panel DP. The anti-reflective layer RPL may be attached to the display panel DP by the third adhesive layer AL3.

The panel protective layer PPL may be located under the display panel DP. The panel protective layer PPL may protect a lower portion of the display panel DP. The panel protective layer PPL may include a flexible plastic material. As an example, the panel protective layer PPL may include polyethylene terephthalate (PET).

The fourth adhesive layer AL4 may be located between the display panel DP and the panel protective layer PPL. The display panel DP may be attached to the panel protective layer PPL by the fourth adhesive layer AL4.

The adhesive layer AL may be located between the panel protective layer PPL and a support plate PLT of the supporter SUP. The panel protective layer PPL may be attached to the support plate PLT by the adhesive layer AL.

The first to fourth adhesive layers AL1 to AL4 and the adhesive layer AL may include a transparent adhesive such as a pressure sensitive adhesive (PSA) or an optically clear adhesive (OCA), however, types of the adhesive should not be particularly limited.

The supporter SUP may include the support plate PLT, a heat dissipation layer RHL, first, second, third, and fourth adhesive layers PSA1, PSA2, PSA3, and PSA4, a cover layer COV, first and second wing plates WPT1 and WPT2, a center single-sided tape TAP, first and second single-sided tapes TAP1 and TAP2, a center plate CPLT, and a folding supporter FSP.

The support plate PLT may be located under the display module DM and may support the display module DM. The support plate PLT may include a metallic or non-metallic material. As an example, the support plate PLT may include a stainless steel or a fiber reinforced composite. The fiber reinforced composite may include a carbon fiber reinforced plastic (CFRP) or a glass fiber reinforced plastic (GFRP).

A plurality of openings POP may be defined through portions of the support plate PLT, which overlap the folding area FA. The openings POP may be formed through the portions of the support plate PLT in the third direction DR3.

The support plate PLT may include a first support plate PLT1, a second support plate PLT2, and a folding plate PLT_F. As an example, boundaries of the first support plate PLT1, the second support plate PLT2, and the folding plate PLT_F are illustrated as dotted lines on the support plate PLT.

The folding plate PLT_F may be located under the display module DM and may be located between the first support plate PLT1 and the second support plate PLT2. The first support plate PLT1, the folding plate PLT_F, and the second support plate PLT2 may be arranged in the first direction DR1. The openings POP may be defined through the folding plate PLT_F.

In the present disclosure, the term “overlap” means that at least portions of components of the display device, which is in the flat state, overlap each other when viewed in the plane (or in a plan view).

The first support plate PLT1 may be located under the display module DM in the first non-folding area NFA1 and may overlap the first non-folding area NFA1. The second support plate PLT2 may be located under the display module DM in the second non-folding area NFA2 and may overlap the second non-folding area NFA2. The folding plate PLT_F may be located under the display module DM in the folding area FA and may overlap the folding area FA.

The folding plate PLT_F may include a curved portion CSP, a first extension portion EX1, a second extension portion EX2, a first reverse curvature portion ICV1, and a second reverse curvature portion ICV2. As an example, boundaries of the curved portion CSP, the first extension portion EX1, the second extension portion EX2, the first reverse curvature portion ICV1, and the second reverse curvature portion ICV2 are shown as dotted lines on the support plate PLT. For convenience, the dotted lines indicating the boundaries are extended to the top of the display module DM, and the reference numerals are depicted on the top of the display module DM.

The curved portion CSP, the first extension portion EX1, the second extension portion EX2, the first reverse curvature portion ICV1, and the second reverse curvature portion ICV2 may be arranged in the first direction DR1. As an example, the curved portion CSP may be located at a center of the folding plate PLT_F. The first reverse curvature portion ICV1 may be defined as a portion of the folding plate PLT_F, which is adjacent to the first support plate PLT1. The second reverse curvature portion ICV2 may be defined as a portion of the folding plate PLT_F, which is adjacent to the second support plate PLT2.

The curved portion CSP may be located between the first extension portion EX1 and the second extension portion EX2. The openings POP may be defined in the curved portion CSP. When the folding plate PLT_F is folded, the curved portion CSP may be folded to have a curvature (e.g., a set or predetermined curvature). Since the openings POP are defined in the curved portion CSP, a flexibility of the curved portion CSP may be relatively improved. Accordingly, the curved portion CSP may be more easily folded. The adhesive layer AL may be opened so as not to overlap the curved portion CSP. That is, the adhesive layer AL may not be located on the curved portion CSP.

The first extension portion EX1 may be located between the curved portion CSP and the first reverse curvature portion ICV1. The second extension portion EX2 may be located between the curved portion CSP and the second reverse curvature portion ICV2.

The first reverse curvature portion ICV1 may be located between the first support plate PLT1 and the curved portion CSP. In detail, the first reverse curvature portion ICV1 may be located between the first support plate PLT1 and the first extension portion EX1. The second reverse curvature portion ICV2 may be located between the second support plate PLT2 and the curved portion CSP. In detail, the second reverse curvature portion ICV2 may be located between the second support plate PLT2 and the second extension portion EX2.

The heat dissipation layer RHL may be located under the support plate PLT. According to some embodiments, the heat dissipation layer RHL may be attached to the support plate PLT by an adhesive layer. The heat dissipation layer RHL may include a metal material. As an example, the heat dissipation layer RHL may include the metal material such as copper. The heat dissipation layer RHL may dissipate heat generated from the display device DD. The heat dissipation layer RHL may be spaced apart from a center of the folding area FA in the first direction DR1. As an example, a portion of the heat dissipation layer RHL, which overlaps the curved portion CSP of the folding plate PLT_F, may be removed and may be divided into portions separated from each other in the first direction DR1.

The heat dissipation layer RHL may include a first heat dissipation layer RHL1 and a second heat dissipation layer RHL2, which are arranged in the first direction DR1. The first heat dissipation layer RHL1 may be located under the first support plate PLT1, the first reverse curvature portion ICV1, and the first extension portion EX1. The second heat dissipation layer RHL2 may be located under the second support plate PLT2, the second reverse curvature portion ICV2, and the second extension portion EX2.

The cover layer COV may be located under the folding plate PLT_F. The cover layer COV may overlap the curved portion CSP of the folding plate PLT_F. The cover layer COV may be in contact with a lower surface of the curved portion CSP through which the openings POP are formed. The cover layer COV located under the folding plate PLT_F may cover the openings POP defined through the folding plate PLT_F.

The cover layer COV may have a modulus of elasticity lower than that of the support plate PLT. As an example, the cover layer COV may include thermoplastic polyurethane or rubber, however, a material for the cover layer COV should not be particularly limited. The cover layer COV may be manufactured in the form of a sheet and may be attached to the support plate PLT.

The cover layer COV may be located between the first heat dissipation layer RHL1 and the second heat dissipation layer RHL2. The first heat dissipation layer RHL1 and the second heat dissipation layer RHL2 may not be in contact with the cover layer COV and may be spaced apart from the cover layer COV. The first and second wing plates WPT1 and WPT2 may be located under

the folding plate PLT_F and may be spaced apart from each other in the first direction DR1. The wing plates WPT1 and WPT2 may include the first wing plate WPT1 and the second wing plate WPT2, which are arranged in the first direction DR1. The first and second wing plates WPT1 and WPT2 may include a metal material.

The first wing plate WPT1 and the second wing plate WPT2 may have a symmetrical shape with respect to the first direction DR1.

The first wing plate WPT1 and the second wing plate WPT2 may be located under the heat dissipation layer RHL. The first wing plate WPT1 may be located under the first heat dissipation layer RHL1, and the second wing plate WPT2 may be located under the second heat dissipation layer RHL2.

The first wing plate WPT1 may be located under the first extension portion EX1 and a portion of the curved portion CSP, which is adjacent to the first extension portion EX1. The first wing plate WPT1 may overlap the first extension portion EX1 and the portion of the curved portion CSP, which is adjacent to the first extension portion EX1.

The second wing plate WPT2 may be located under the second extension portion EX2 and a portion of the curved portion CSP, which is adjacent to the second extension portion EX2. The second wing plate WPT2 may overlap the second extension portion EX2 and the portion of the curved portion CSP, which is adjacent to the second extension portion EX2.

The first single-sided tape TAP1 may be located on an upper surface of the first wing plate WPT1. The first single-sided tape TAP1 may be attached to the upper surface of the first wing plate WPT1. The first single-sided tape TAP1 may be located between the first wing plate WPT1 and the first heat dissipation layer RHL1 in an area overlapping the first extension portion EX1. The first single-sided tape TAP1 may not be attached to the first heat dissipation layer RHL1, however, the present disclosure should not be limited thereto or thereby. According to some embodiments, the first wing plate WPT1 may be attached to the first heat dissipation layer RHL1 by a double-sided tape.

The second single-sided tape TAP2 may be located on an upper surface of the second wing plate WPT2. The second single-sided tape TAP2 may be attached to the upper surface of the second wing plate WPT2. The second single-sided tape TAP2 may be located between the second wing plate WPT2 and the second heat dissipation layer RHL2 in an area overlapping the second extension portion EX2. The second single-sided tape TAP2 may not be attached to the second heat dissipation layer RHL2, however, embodiments according to the present disclosure are not limited thereto or thereby. According to some embodiments, the second wing plate WPT2 may be attached to the second heat dissipation layer RHL2 by a double-sided tape.

The center plate CPLT may be located under the folding plate PLT_F and may overlap the curved portion CSP. The center plate CPLT may be located between the first wing plate WPT1 and the second wing plate WPT2. According to some embodiments, the center plate CPLT may be connected to a hinge to fold the display device. The center plate CPLT may include a metal material.

The folding supporter FSP may be located between the center plate CPLT and the folding plate PLT_F. When viewed in the plane (or in a plan view), the folding supporter FSP may overlap the openings POP defined through the folding plate PLT_F. The folding supporter FSP may overlap a portion of the cover layer COV. As an example, the folding supporter FSP may be arranged to overlap a center of the cover layer COV.

An upper surface of the folding supporter FSP may be located higher than lower ends of both sides of the cover layer COV. Accordingly, the folding supporter FSP may cause the portion of the cover layer COV overlapping the folding supporter FSP to protrude upward by a height (e.g., a set or predetermined height). As the portion of the cover layer COV protrudes upward, the curved portion CSP may protrude upward.

The cover layer COV may be located between the folding supporter FSP and the folding plate PLT_F. The folding supporter FSP may have a width smaller than a width of the cover layer COV.

According to some embodiments, a portion of a lower surface of the cover layer COV may be processed, and the folding supporter FSP may be inserted into the processed portion of the cover layer COV. As an example, a groove may be formed in the lower surface of the cover layer COV, and an upper portion of the folding supporter FSP may be inserted into the groove formed in the lower surface of the cover layer COV.

A first flat plate SPT1 may be located under the first heat dissipation layer RHL1, and a second flat plate SPT2 may be located under the second heat dissipation layer RHL2. The first and second adhesive layers PSA1 and PSA2 may be located between the first heat dissipation layer RHL1 and the first flat plate SPT1. The first heat dissipation layer RHL1 and the first flat plate SPT1 may be attached to each other by the first and second adhesive layers PSA1 and PSA2.

The third and fourth adhesive layers PSA3 and PSA4 may be located between the second heat dissipation layer RHL2 and the second flat plate SPT2. The second heat dissipation layer RHL2 and the second flat plate SPT2 may be attached to each other by the third and fourth adhesive layers PSA3 and PSA4.

The first and second wing plates WPT1 and WPT2 may be located between the first flat plate SPT1 and the second flat plate SPT2. The first flat plate SPT1 may be located adjacent to the first wing plate WPT1 in the first direction DR1. The second flat plate SPT2 may be located adjacent to the second wing plate WPT2 in the first direction DR1.

The first wing plate WPT1 may be located between the center plate CPLT and the first flat plate SPT1. The second wing plate WPT2 may be located between the center plate CPLT and the second flat plate SPT2.

The center single-sided tape TAP may be located on an upper surface of the center plate CPLT. The center single-sided tape TAP may be attached to the upper surface of the center plate CPLT. The center single-sided tape TAP may be located between the folding supporter FSP and the center plate CPLT.

The folding supporter FSP may be located on the center single-sided tape TAP. The folding supporter FSP may be attached to the center single-sided tape TAP. As an example, an adhesive may be located on the lower surface of the folding supporter FSP, and then the folding supporter FSP may be attached to the center single-sided tape TAP.

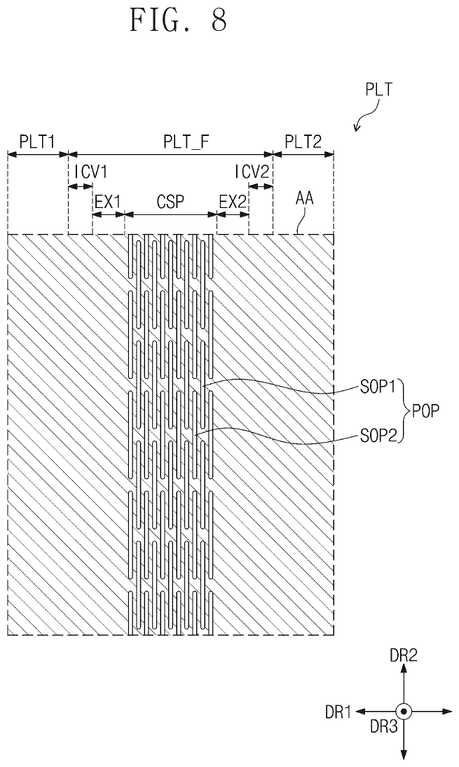

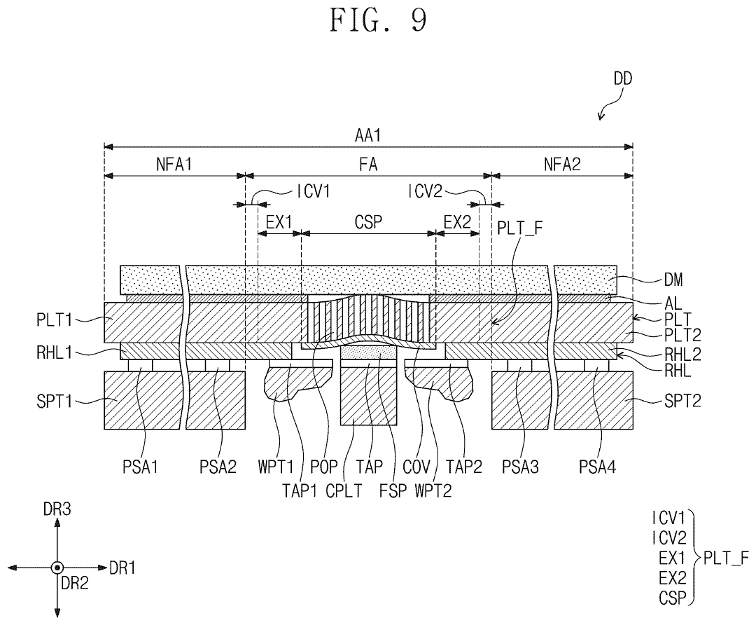

FIG. 7 is a perspective view of the support plate PLT shown in FIG. 6, and FIG. 8 is an enlarged plan view of an area AA shown in FIG. 7.

Referring to FIGS. 7 and 8, the support plate PLT may include the first support plate PLT1, the folding plate PLT_F, and the second support plate PLT2, which are arranged in the first direction DR1. The folding plate PLT_F may include the first reverse curvature portion ICV1, the first extension portion EX1, the curved portion CSP, the second extension portion EX2, and the second reverse curvature portion ICV2, which are arranged in the first direction DR1.

A grid pattern may be defined in the curved portion CSP. As an example, the openings POP defined through the curved portion CSP may be arranged in a certain rule. The openings POP may be arranged in the form of grid to form the grid pattern of the curved portion CSP.

A first hole H1 and a second hole H2 may be defined through the second support plate PLT2. The first hole H1 and the second hole H2 may be defined adjacent to an edge of the second support plate PLT2. The camera CA and the sensor SN may be located in the first hole H1 and the second hole H2, respectively.

The openings POP may extend longer in the second direction DR2 than in the first direction DR1. The openings POP may include a plurality of first sub-openings SOP1 arranged in the second direction DR2 and a plurality of second sub-openings SOP2 adjacent to the first sub-openings SOP1 in the first direction DR1 and arranged in the second direction DR2. The first sub-openings SOP1 may be arranged staggered with the second sub-openings SOP2.

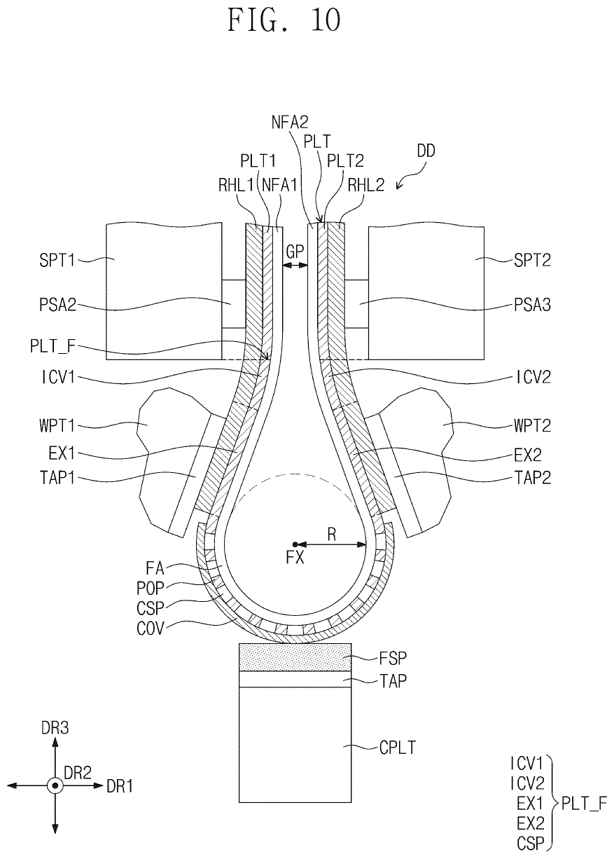

FIG. 9 is a view schematically illustrating the display device DD shown in FIG. 6.

As an example, the display module DM is schematically illustrated as a single layer in FIG. 9.

Referring to FIG. 9, the folding supporter FSP may be located under the cover layer COV and may support the cover layer COV and the curved portion CSP of the folding plate PLT_F.

The folding supporter FSP may include a polymer-based porous material or a polymer-based membrane material. The folding supporter FSP may have a tear strength in a range from 1 kg to 10 kg (or about 1 kg to about 10 kg). The folding supporter FSP may have a compression force deflection (CFD) in a range from 0.01 MPa to 0.05 MPa (or about 0.01 MPa to about 0.05 MPa).

As the portion of the cover layer COV protrudes upward due to the folding supporter FSP, the curved portion CSP of the folding plate PLT-F may protrude upward. The portion of the curved portion CSP, which protrudes upward, may overlap the center of the folding area FA. The portion of the curved portion CSP, which protrudes upward, may support the center of the folding area FA. As an example, the portion of the curved portion CSP, which protrudes upward, may be in contact with the center of the folding area FA. The center of the folding area FA may be the portion folded with respect to the folding axis FX.

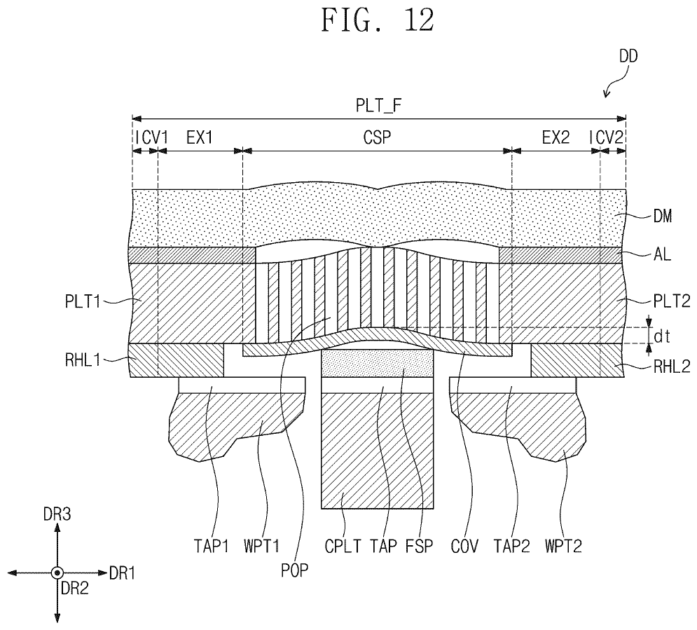

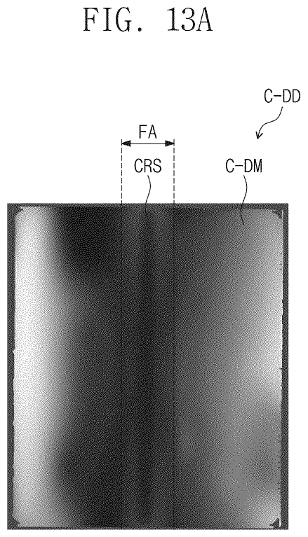

The display device DD may be folded and unfolded. When the display device DD is repeatedly folded and unfolded, the folding area FA and the folding plate PLT_F may be deformed and sagged downward. According to the present disclosure, as the portion of the curved portion CSP, which protrudes upward by the folding supporter FSP, supports the portion of the folding area FA, the portion of the folding area FA may not be sagged downward. This structure will be described in detail with reference to FIGS. 11 and 12.

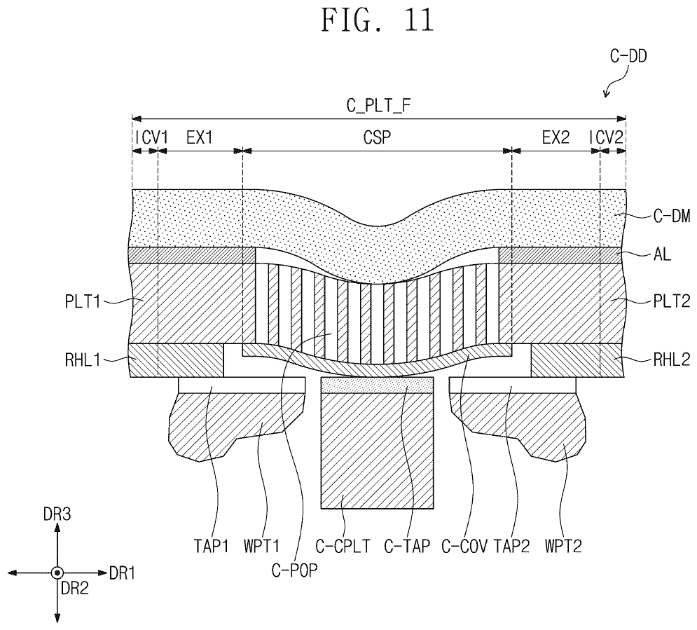

FIG. 10 is a view of a folded state of the display device DD shown in FIG. 9.

In FIG. 10, for the convenience of explanation, the display module and the support plate are illustrated as being relatively thinner than those in FIG. 9.

As an example, boundaries of the first and second support plates PLT1 and PLT2, the curved portion CSP, the first and second extension portions EX1 and EX2, and the first and second reverse curvature portions ICV1 and ICV2 are illustrated as dotted lines on the support plate PLT.

Referring to FIG. 10, the support plate PLT may be folded with respect to the folding axis FX. The support plate PLT may be folded to have a dumbbell shape. As the support plate PLT is folded, the display module DM may be folded together with the support plate PLT.

The folding plate PLT_F may be folded with respect to the folding axis FX, and thus, the support plate PLT may be folded. When the folding plate PLT_F is folded, the curved portion CSP may be folded with a curvature (e.g., a set or predetermined curvature). As an example, the folding area FA of the display module DM on the curved portion CSP may be curved to have the radius of curvature R.

The first reverse curvature portion ICV1 may be curved opposite to the curved portion CSP. The second reverse curvature portion ICV2 may be curved opposite to the curved portion CSP. The second reverse curvature portion ICV2 may have a symmetrical shape with respect to the first reverse curvature portion ICV1.

When the folding plate PLT_F is folded, the first support plate PLT1 and the second support plate PLT2 may be maintained in the flat state. Accordingly, the first and second non-folding areas NFA1 and NFA2 may be maintained in the flat state by the first and second support plates PLT1 and PLT2.

When the folding plate PLT_F is folded, the first and second flat plates SPT1 and SPT2 may also be maintained in the flat state.

When folding plate PLT_F is folded, a distance GP in the first direction DR1 between the first support plate PLT1 and the second support plate PLT2 may be smaller than a diameter of the circle having the radius of curvature R. Accordingly, the support plate PLT may be folded with the dumbbell shape.

When the folding plate PLT_F is folded, a portion of a first shielding layer SHL1, which overlaps the first reverse curvature portion ICV1, may be curved to correspond to a shape of the first reverse curvature portion ICV1. When the folding plate PLT_F is folded, a portion of a second shielding layer SHL2, which overlaps the second reverse curvature portion ICV2, may be curved to correspond to a shape of the second reverse curvature portion ICV2.

The first extension portion EX1 may be maintained in the flat state between the curved portion CSP and the first reverse curvature portion ICV1. The first extension portion EX1 may be maintained in the flat state while extending from the first reverse curvature portion ICV1 to the curved portion CSP.

The second extension portion EX2 be maintained in the flat state between the curved portion CSP and the second reverse curvature portion ICV2. The second extension portion EX2 may be maintained in the flat state while extending from the second reverse curvature portion ICV2 to the curved portion CSP.

The cover layer COV may be curved together with the curved portion CSP.

The folding supporter FSP, the center single-sided tape TAP, and the center plate CPLT may be located under the cover layer COV. When the display device DD is folded, the folding supporter FSP may be in contact with a portion of the cover layer COV. As an example, the folding supporter FSP may be in contact with a center of the cover layer COV with respect to the folding axis FX in the third direction DR3. The folding supporter FSP may be maintained in the flat state without being curved. The folding supporter FSP may support the curved portion CSP overlapping the portion of the cover layer COV.

FIG. 11 is a cross-sectional view of a folding plate and a folding area of a comparative display device in a state in which the comparative display device C-DD has been repeatedly folded and unfolded according to a comparative embodiment.

FIG. 11 shows a cross-section corresponding to the display device DD of FIG. 9, and hereinafter, descriptions will be focused on components of FIG. 11 that are different from those of FIG. 9.

Referring to FIG. 11, a folding supporter FSP may not be located on a center plate C-CPLT of the comparative display device C-DD. When the comparative display device C-DD is repeatedly folded and unfolded, a folding area FA and a curved portion CSP may be deformed. In this case, the deformed folding area FA and the deformed curved portion CSP may be sagged downward. Accordingly, a cover layer C-COV may also be sagged downward. The sagged cover layer C-COV may be in contact with a center single-sided tape C-TAP. When the folding area FA and the curved portion CSP sag beyond a certain depth, the folding area FA and the curved portion CSP may be viewed as creases.

FIG. 12 is an enlarged view of the folding plate and the folding area after the display device shown in FIG. 9 is repeatedly folded and unfolded.

Referring to FIG. 12, the folding supporter FSP may be located above the center plate CPLT. As described above, when the radius of curvature of the folding area FA is R, a width in the first direction DR1 of the folding supporter FSP may be set as the radius of curvature R to πR+1. A distance dt between an upper end of both sides of the cover layer COV, which are opposite to each other in the first direction DR1, and an uppermost end of the upper surface of the cover layer COV may be within a range from 0 μm to 50 μm (or about 0 um to about 50 (m).

As described above, the portion of the cover layer COV may protrude upward by the folding supporter FSP. As the cover layer COV protrudes upward, the curved portion CSP of the folding plate PLT_F may protrude upward. When the display device DD is repeatedly folded and unfolded, the folding area FA and the folding plate PLT_F may be deformed and sagged as the comparative display device C-DD shown in FIG. 11.

According to some embodiments, the folding supporter FSP may support the portion of the folding area FA where the upwardly protruded portion of the curved portion CSP may be sagged. Accordingly, the deformed portion of the folding area FA may not be sagged. In this case, the creases may not be viewed in the folding area FA.

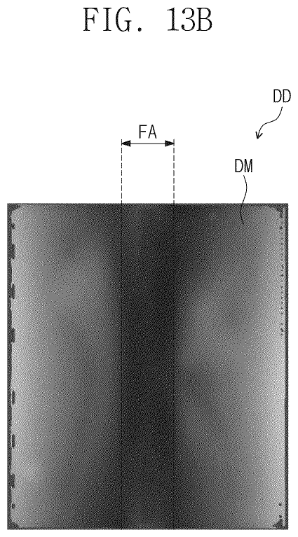

FIG. 13A is a photograph showing a folding test result of the comparative display device C-DD shown in FIG. 11, and FIG. 13B is a photograph showing a folding test result of the display device DD shown in FIG. 12.

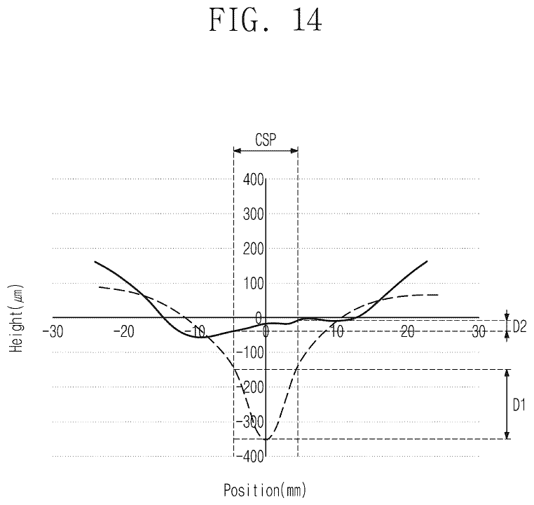

FIG. 14 is a graph illustrating a deformation amount of a comparative display module and the display module according to folding test results of the comparative display device and the display device of the present disclosure.

As an example, FIGS. 13A and 13B illustrate the test results measured after the comparative display device C-DD and the display device DD are repeatedly folded and unfolded at a temperature of 60° C. (or about 60° C.) for 2 hours (or about 2 hours).

In FIG. 14, a vertical axis is in micrometers, and a horizontal axis, which shows left and right lengths centered on the folding axis FX, is in millimeters.

Referring to FIGS. 13A and 14, the portion of the comparative display module C-DM, which overlaps the curved portion CSP, is drastically deformed. As an example, in FIG. 14, the deformation amount of the comparative display module C-DM of the comparative display device C-DD, which overlaps the curved portion CSP, is defined as a first deformation amount D1. In this case, creases CRS are formed as shown in FIG. 13A and perceived by the user. The first deformation amount D1 is measured of 220 micrometers (or about 220 micrometers).

Referring to FIGS. 13B and 14, the portion of the display module DM, which overlaps the curved portion CSP, is slightly deformed. As an example, the deformation amount of the portion of the display module DM, which overlaps the curved portion CSP, is defined as a second deformation amount D2. The second deformation amount D2 is smaller than the first deformation amount D1. As an example, the second deformation amount D2 is measured of 14 micrometers (or about 14 micrometers). In this case, the creases are not perceived by the user as shown in FIG. 13B.

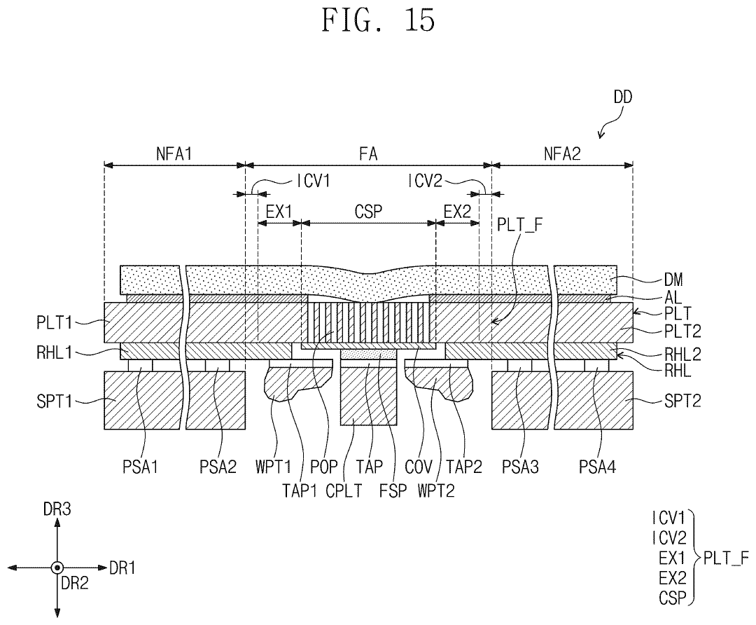

FIGS. 15 to 20 are cross-sectional views of display devices according to embodiments of the present disclosure.

As an example, FIGS. 15 to 20 show cross-sections corresponding to that of FIG. 12, and hereinafter, descriptions will be focused on components of FIGS. 15 to 20 that are different from those of FIG. 12.

Referring to FIG. 15, a folding supporter FSP may be located above a center plate CPLT. An upper surface of the folding supporter FSP and a lower surface of a cover layer COV may be flat. The folding supporter FSP may be in contact with the lower surface of the cover layer COV without lifting the cover layer COV upward and may support the cover layer COV from beneath the cover layer COV. The folding supporter FSP may support a folding plate PLT_F overlapping the cover layer COV that is in contact with the folding supporter FSP. The folding supporter FSP may support a curved portion CSP of the folding plate PLT_F together with the cover layer COV. The curved portion CSP may be in contact with a center of a folding area FA of a display module DM. Accordingly, the folding supporter FSP may support the center of the display module DM in the folding area FA together with the cover layer COV and the folding plate PLT_F.

As a result, since the folding supporter FSP supports the curved portion CSP and the display module DM in the folding area FA when the display device DD is repeatedly folded and unfolded, sagging of the curved portion CSP and the display module DM in the folding area FA may be prevented or reduced.

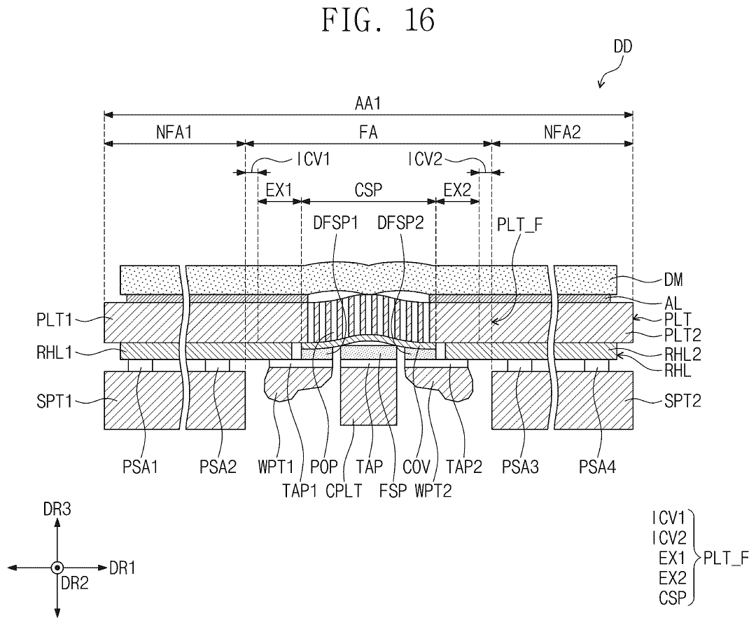

Referring to FIG. 16, a folding supporter FSP may be located above a center plate CPLT. A plurality of dummy folding supporters DFSP1 and DFSP2 may be located between a folding plate PLT_F and first and second wing plates WPT1 and WPT2 and. The dummy folding supporters DFSP1 and DFSP2 may overlap a curved portion CSP of the folding plate PLT_F. The dummy folding supporters DFSP1 and DFSP2 may include a first dummy folding supporter DFSP1 and a second dummy folding supporter DFSP2.

The first dummy folding supporter DFSP1 may be located under the curved portion CSP adjacent to a first extension portion EX1. The second dummy folding supporter DFSP2 may be located under the curved portion CSP adjacent to a second extension portion EX2. The first and second dummy folding supporters DFSP1 and DFSP2 may efficiently support the curved portion CSP together with the folding supporter FSP. Accordingly, the curved portion CSP and the display module DM in the folding area FA may be supported by the first and second dummy folding supporters DFSP1 and DFSP2 and the folding supporter FSP.

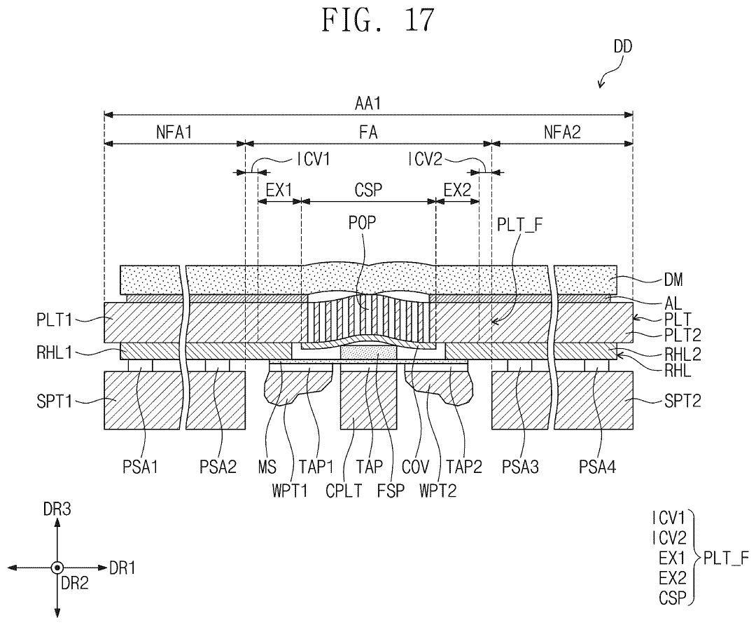

Referring to FIG. 17, a metal sheet MS may be located between a folding plate PLT_F and first and second wing plates WPT1 and WPT2 and between a center plate CPLT and a folding supporter FSP.

According to some embodiments, the first and second wing plates WPT1 and WPT2 may be connected to first and second flat plates SPT1 and SPT2 by additional mechanical structures to rotate. When the display device DD is repeatedly folded and unfolded, the first and second wing plates WPT1 and WPT2 may rotate with the first and second flat plates SPT1 and SPT2, and a difference in height between an upper surface of the first wing plate WPT1 and an upper surface of the second wing plate WPT2 may occur.

The metal sheet MS may cover the upper surfaces of the first and second wing plates WPT1 and WPT2 and an upper surface of the center plate CPLT. The metal sheet MS may allow the upper surfaces of the first and second wing plates WPT1 and WPT2 and the upper surface of the center plate CPLT to be flat. Accordingly, the difference in height between the upper surface of the center plate CPLT and the upper surfaces of the first and second wing plates WPT1 and WPT2 may be reduced by the metal sheet MS.

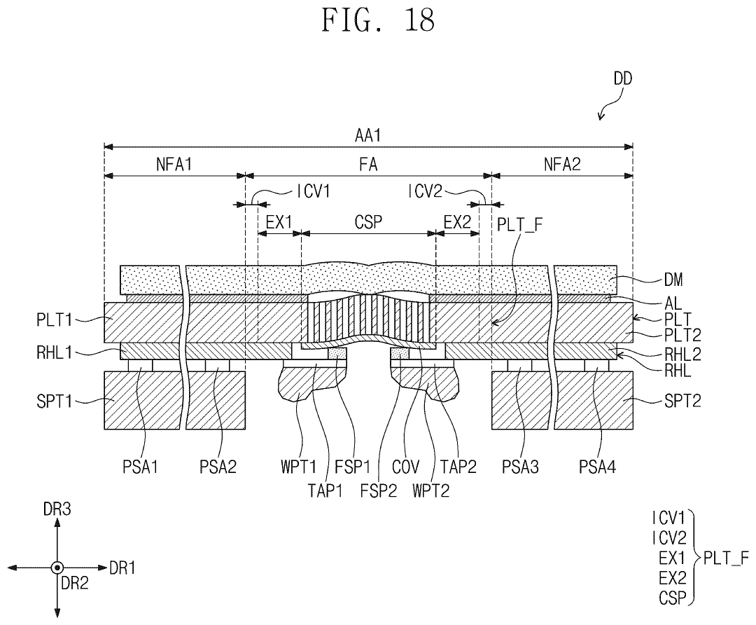

Referring to FIG. 18, a center plate CPLT (refer to FIG. 6) may not be located between first and second wing plates WPT1 and WPT2 in the display device DD. A first folding supporter FSP1 may be located between the first wing plate WPT1 and a folding plate PLT_F. A second folding supporter FSP2 may be located between the second wing plate WPT2 and the folding plate PLT_F. The first folding supporter FSP1 and the second folding supporter FSP2 may be spaced apart from each other in the first direction DR1.

The first folding supporter FSP1 may be located on the first wing plate WPT1 to overlap a portion of a curved portion CSP, which is adjacent to a first extension portion EX1. The second folding supporter FSP2 may be located on the second wing plate WPT2 to overlap a portion of the curved portion CSP, which is adjacent to a second extension portion EX2.

The portions of the curved portion CSP, which overlap the first and second folding supporters FSP1 and FSP2, may be lifted upward by the first and second folding supporters FSP1 and FSP2, and thus, a center of the curved portion CSP may protrude upward. Accordingly, the curved portion CSP protruding upward by the first and second folding supporters FSP1 and FSP2 may support a portion of the display module DM in the folding area FA that may sag downward.

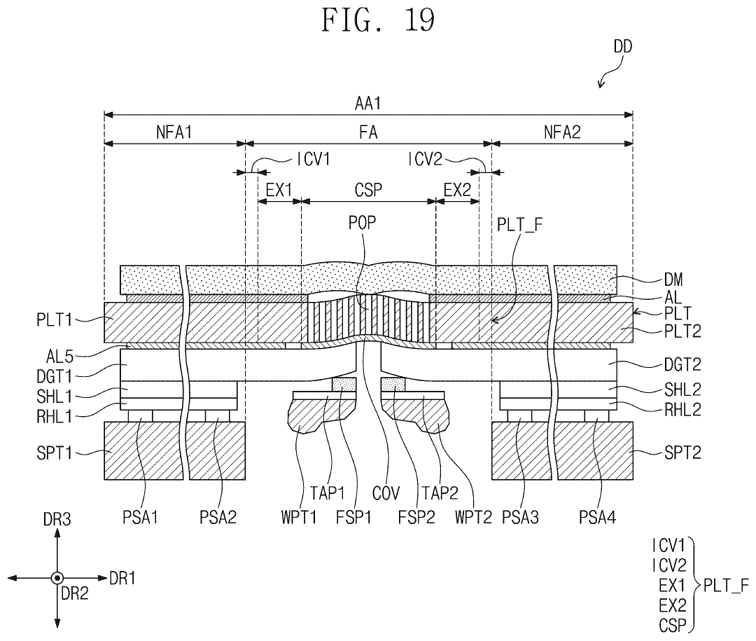

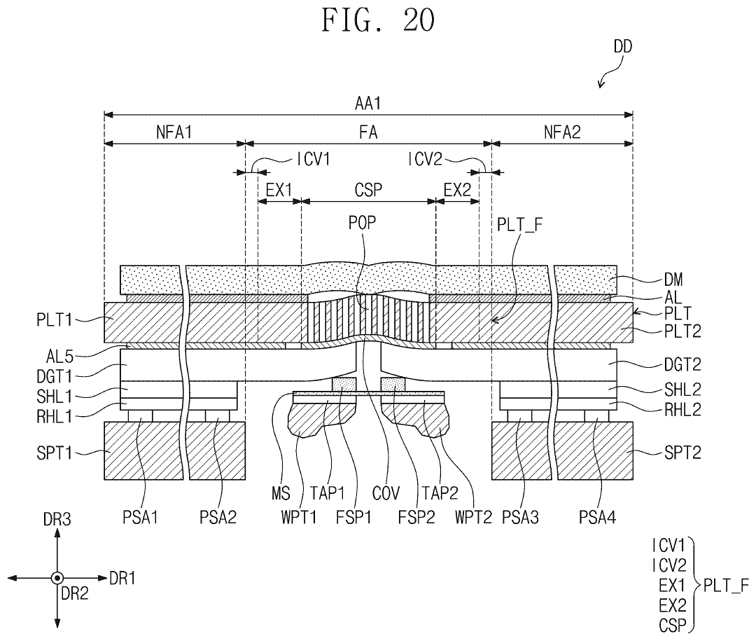

Referring to FIGS. 19 and 20, a digitizer DGT1 and DGT2 may be located between a support plate PLT and first and second folding supporters FSP1 and FSP2. A fifth adhesive layer AL5 may be located on the digitizer DGT1 and DGT2. The digitizer DGT1 and DGT2 may be attached to the support plate PLT by the fifth adhesive layer AL5.

The digitizer DGT1 and DGT2 may be divided into two portions under a folding plate PLT_F. The digitizer DGT1 and DGT2 may include a first digitizer DGT1 and a second digitizer DGT2, which are separated from each other and arranged in the first direction DR1. The first digitizer DGT1 may be located under a first support plate PLT1, and the second digitizer DGT2 may be located under a second support plate PLT2.

According to some embodiments, the first digitizer DGT1 and the second digitizer DGT2, which are separated from each other, may be connected to a digitizer driver via a flexible circuit board.

The first digitizer DGT1 may overlap the first support plate PLT1 and a portion of the folding plate PLT_F, which is adjacent to the first support plate PLT1. As an example, the first digitizer DGT1 may overlap a first reverse curvature portion ICV1, a first extension portion EX1, and a portion of a curved portion CSP, which is adjacent to the first extension portion EX1.

The second digitizer DGT2 may overlap the second support plate PLT2 and a portion of the folding plate PLT_F, which is adjacent to the second support plate PLT2. As an example, the second digitizer DGT2 may overlap a second reverse curvature portion ICV2, a second extension portion EX2, and a portion of the curved portion CSP, which is adjacent to the second extension portion EX2.

First and second shielding layers SHL1 and SHL2 may be located under the first and second digitizers DGT1 and DGT2, respectively. In detail, the first and second shielding layers SHL1 and SHL2 may include a magnetic metal powder. The first and second shielding layers SHL1 and SHL2 may shield electromagnetic fields applied to the digitizer DGT from beneath the display device DD. The first and second shielding layers SHL1 and SHL2 may be defined as an electromagnetic field shielding layer.

The first and second shielding layers SHL1 and SHL2 may be in contact with a lower surface of the digitizer DGT1 and DGT2. The first and second shielding layers SHL1 and SHL2 may be attached directly to the lower surface of the digitizer DGT1 and DGT2 without using an adhesive layer.

First and second heat dissipation layers RHL1 and RHL2 may be located under the first and second shielding layers SHL1 and SHL2, respectively. The first and second heat dissipation layers RHL1 and RHL2 may perform a heat dissipation function. As an example, the first and second heat dissipation layers RHL1 and RHL2 may include copper or graphite, however, a material for the first and second heat dissipation layers RHL1 and RHL2 should not be limited thereto or thereby. According to some embodiments, the first and second heat dissipation layers RHL1 and RHL2 may be attached to the first and second shielding layers SHL1 and SHL2, respectively, by an adhesive.

The first folding supporter FSP1 may be located between a first wing plate WPT1 and the folding plate PLT_F. A first single-sided tape TAP1 may be located on an upper surface of the first wing plate WPT1. The first folding supporter FSP1 may be located on the first single-sided tape TAP1. The first folding supporter FSP1 may be located on a lower surface of the first digitizer DGT1.

The first folding supporter FSP1 may be arranged to overlap the portion of the curved portion CSP, which is adjacent to the first extension portion EX1. A portion of the first digitizer DGT1, which overlaps the portion of the curved portion CSP adjacent to the first extension portion EX1, may protrude upward by a height (e.g., a set or predetermined height) due to the first folding supporter FSP1. As the portion of the first digitizer DGT1 protrudes upward, a portion of a cover layer COV and the curved portion CSP may protrude upward.

The second folding supporter FSP2 may be located between a second wing plate WPT2 and the folding plate PLT_F. A second single-sided tape TAP2 may be attached to an upper surface of the second wing plate WPT2. The second folding supporter FSP2 may be located on the second single-sided tape TAP2. The second folding supporter FSP2 may be located on a lower surface of the second digitizer DGT2.

The second folding supporter FSP2 may be arranged to overlap the portion of the curved portion CSP, which is adjacent to the second extension portion EX2. A portion of the second digitizer DGT2, which overlaps the portion of the curved portion CSP adjacent to the second extension portion EX2, may protrude upward by a height (e.g., a set or predetermined height) due to the second folding supporter FSP2. As the portion of the second digitizer DGT2 protrudes upward, a portion of the cover layer COV and the curved portion CSP may protrude upward.

As described above, since the portions of the first and second digitizers DGT1 and DGT2 protrude upward by the first folding supporter FSP1 and the second folding supporters FSP2, the cover layer COV and the curved portion CSP, which protrude upward, may support the display module in the folding area FA. As the portion of the curved portion CSP protruded upward by the first folding supporter FSP1 and the second folding supporters FSP2 supports the portion of the display module DM in the folding area FA that may sag downward, the deformed portion of the display module DM in the folding area FA may not sag downward.

Referring to FIG. 20, a metal sheet MS may be located between first and second wing plates WPT1 and WPT2 and first and second folding supporters FSP1 and FSP2. The metal sheet may have the same (or substantially the same) function as that described with reference to FIG. 17.

That is, the metal sheet MS may function to allow upper surfaces of the first and second wing plates WPT1 and WPT2 to be flat. Accordingly, a difference in height between the upper surfaces of the first and second wing plates WPT1 and WPT2 may be reduced by the metal sheet MS.

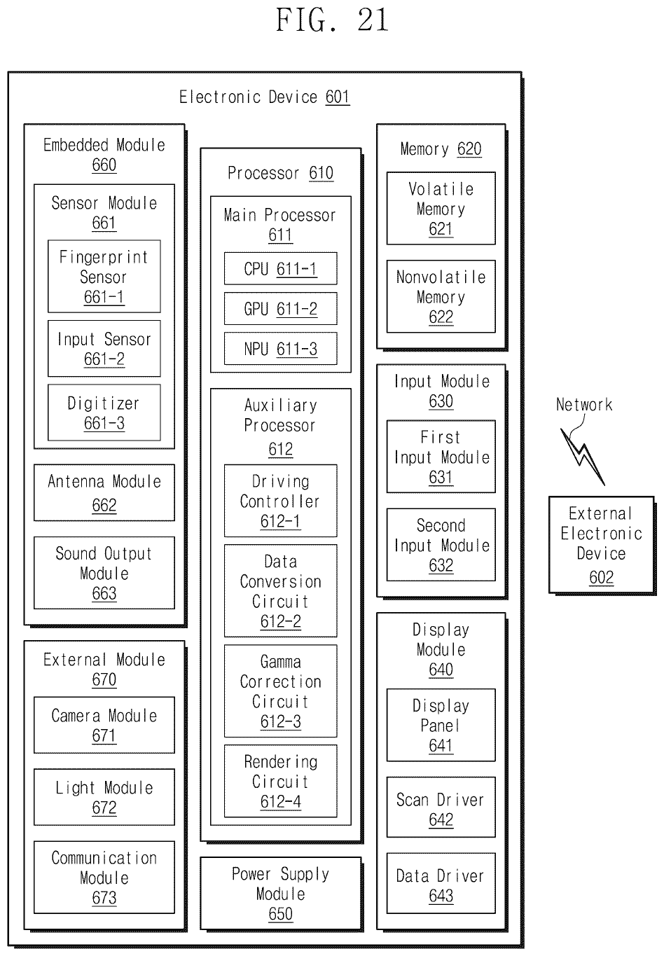

FIG. 21 is a block diagram of an electronic device, according to some embodiments of the present disclosure.

Referring to FIG. 21, an electronic device 601 outputs various pieces of information through a display module 640 within an operating system. When a processor 610 executes an application stored in a memory 620, a display module 640 provides application information to a user through a display panel 641.

The processor 610 obtains an external input through an input module 630 or a sensor module 661 and executes an application corresponding to the external input. For example, when the user selects a camera icon displayed on the display panel 641, the processor 610 obtains a user input through an input sensor 661-2 and activates a camera module 671. The processor 610 delivers image data corresponding to a captured image obtained through the camera module 671 to the display module 640. The display module 640 may display an image corresponding to the captured image through the display panel 641.

For another example, when personal information is authenticated on the display module 640, a fingerprint sensor 661-1 obtains entered fingerprint information as input data. The processor 610 compares input data obtained through the fingerprint sensor 661-1 with authentication data stored in the memory 620 and executes an application based on the comparison result. The display module 640 may display information, which is executed depending on the logic of the application, through the display panel 641.

For another example, when a music streaming icon displayed on the display module 640 is selected, the processor 610 obtains a user input through the input sensor 661-2 and activates the music streaming application stored in the memory 620. When a music play command is input by the music streaming application, the processor 610 provides sound information corresponding to the music play command to the user by activating a sound output module 663.

The operation of the electronic device 601 has been briefly described above. Hereinafter, a configuration of the electronic device 601 will be described in detail. Some of components of the electronic device 601, which will be described below, may be integrated and provided as one configuration, or the one configuration may be provided to be separated into two or more configurations.

Referring to FIG. 21, the electronic device 601 may communicate with an external electronic device 602 through a network (e.g., a short-range wireless communication network or a long-range wireless communication network). According to some embodiments, the electronic device 601 may include the processor 610, the memory 620, the input module 630, the display module 640, a power supply module 650, an embedded module 660, and an external module 670. According to some embodiments, in the electronic device 601, at least one of the above-described components may be omitted, or one or more other components may be added. According to some embodiments, some (e.g., the sensor module 661, an antenna module 662, or the sound output module 663) of the components described above may be integrated into another component (e.g., the display module 640).

The processor 610 may execute software to control at least another component (e.g., hardware or software component) of the electronic device 601 connected to the processor 610, and may process and calculate various types of data. According to some embodiments, as at least part of data processing or calculation, the processor 610 may store instructions or data received from other components (e.g., the input module 630, the sensor module 661 or a communication module 673) into a volatile memory 621, may process instructions or data stored in the volatile memory 621. The result data may be stored in a nonvolatile memory 622.

The processor 610 may include a main processor 611 and an auxiliary processor 612. The main processor 611 may include one or more of a central processing unit (CPU) 611-1 or an application processor (AP). The main processor 611 may further include one or more of a graphic processing unit (GPU) 611-2, a communication processor (CP), and an image signal processor (ISP). The main processor 611 may further include a neural processing unit (NPU) 611-3. The NPU 611-3 may be a processor that is specialized in processing an artificial intelligence model. The artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the networks, but may not be limited to the above-described example. In addition to a hardware structure, additionally or alternatively, the artificial intelligence model may include a software structure. At least two of the processing units and the processors that are described above may be implemented as one integrated component (e.g., a single chip) or may be implemented as independent components (e.g., a plurality of chips).

The auxiliary processor 612 may include a driving controller 612-1. The driving controller 612-1 may include an interface converting circuit and a timing control circuit. The driving controller 612-1 receives an image signal from the main processor 611, converts the data format of the image signal so as to be suitable for the interface specifications with the display module 640, and outputs image data. The driving controller 612-1 may output various control signals required to drive the display module 640.

The auxiliary processor 612 may further include a data converting circuit 612-2, a gamma correcting circuit 612-3, and a rendering circuit 612-4. The data converting circuit 612-2 may receive the image data from the driving controller 612-1 and may compensates for the image data such that an image is displayed at a desired luminance according to characteristics of the electronic device 601 or setting of the user or may convert the image data to reduce power consumption or compensate for afterimages. The gamma correcting circuit 612-3 may convert the image data, a gamma reference voltage, or the like such that the image displayed on the electronic device 601 has desired gamma characteristics. The rendering circuit 612-4 may receive the image data from the driving controller 612-1 and may render the image data in consideration of a pixel arrangement of the display panel 641 applied to the electronic device 601. At least one of the data converting circuit 612-2, the gamma correcting circuit 612-3, or the rendering circuit 612-4 may be integrated into another component (e.g., the main processor 611 or the driving controller 612-1). At least one of the data converting circuit 612-2, the gamma correcting circuit 612-3, or the rendering circuit 612-4 may be integrated into a data driver 643.

The memory 620 may store various pieces of data, which are used by at least one component (e.g., the processor 610 or the sensor module 661) of the electronic device 601 and input data or output data for commands related thereto. The memory 620 may include at least one or more of the volatile memory 621 and the nonvolatile memory 622.

The input module 630 may receive, from the outside (e.g., the user or an external electronic device 602) of the electronic device 601, commands or data to be used in a components (e.g., the processor 610, the sensor module 661, or the sound output module 663) of the electronic device 601.

The input module 630 may include a first input module 631, through which the commands or data are input from the user, and a second input module 632 through which the commands or data are input from the external electronic device 602. The first input module 631 may include a microphone, a mouse, a keyboard, a key (e.g., a button), or a pen (e.g., a passive pen or an active pen). The second input module 632 may support a designated protocol capable of being connected to the external electronic device 602 by wire or wirelessly. According to some embodiments, the second input module 632 may include a high definition multimedia interface (HDMI), a universal serial bus (USB) interface, a secure digital (SD) card interface, or an audio interface. The second input module 632 may include a connector that may be physically connected to the external electronic device 602, for example, an HDMI connector, a USB connector, an SD card connector, or an audio connector (e.g., a headphone connector).

The display module 640 provides visual information to the user. The display module 640 may include the display panel 641, a scan driver 642, and the data driver 643. The display module 640 may further include a window, a chassis, a bracket, or the like for protecting the display panel 641. The display module 640 may further include a light emitting driver, a voltage generator, and the like. The voltage generator may output various voltages (e.g., the first and second driving voltages ELVDD and ELVSS (see FIG. 1)) required to drive the display panel 641.

The power supply module 650 supplies power to the components of the electronic device 601. The power supply module 650 may include a battery that charges a power voltage. The battery may include a non-rechargeable primary cell, a rechargeable secondary cell, a fuel cell, or the like. The power supply module 650 may include a power management integrated circuit (PMIC). The PMIC supplies optimized power to the above-described modules and modules which will be described below. The power supply module 650 may include a wireless power transmission/reception member electrically connected to the battery. The wireless power transmission/reception member may include a plurality of coil-shaped antenna radiators.

The electronic device 601 may further include the embedded module 660 and the external module 670. The embedded module 660 may include the sensor module 661, the antenna module 662, and the sound output module 663. The external module 670 may include the camera module 671, a light module 672, and the communication module 673.

The sensor module 661 may detect an input from the user's body or an input from a pen among the first input module 631, and may generate an electrical signal or data value corresponding to the input. The sensor module 661 may include at least one of the fingerprint sensor 661-1, the input sensor 661-2, or a digitizer 661-3.

The fingerprint sensor 661-1 may generate a data value corresponding to a fingerprint of the user. The fingerprint sensor 661-1 may include one of an optical-type fingerprint sensor, or a capacitance-type fingerprint sensor.

The input sensor 661-2 may generate a data value corresponding to coordinate information of an input by a body of the user or an input by a pen. The input sensor 661-2 generates the change in capacitance due to the input as the data value. The input sensor 661-2 may sense an input by a passive pen or may transmit or receive data to or from an active pen.

The input sensor 661-2 may also measure a biometric signal such as blood pressure, moisture, or body fat. For example, when the user touches a part of the body to a sensor layer or sensing panel and does not move during a specific period, the input sensor 661-2 may detect the biometric signal and may output information desired by the user to the display module 640 based on a changes in electric fields caused by the part of the body.

The digitizer 661-3 may generate the data value corresponding to coordinate information of an input by the pen. The digitizer 661-3 generates an electromagnetic change amount due to the input as the data value. The digitizer 661-3 may sense input by the passive pen or transmit or receive data to or from the active pen.

At least one of the fingerprint sensor 661-1, the input sensor 661-2, or the digitizer 661-3 may be implemented as a sensor layer formed on the display panel 641 through a subsequent process. The fingerprint sensor 661-1, the input sensor 661-2, and the digitizer 661-3 may be placed on the upper side of the display panel 641, and one (e.g., the digitizer 661-3) of the fingerprint sensor 661-1, the input sensor 661-2, and the digitizer 661-3 may be placed on the lower side of the display panel 641.

At least two or more of the fingerprint sensor 661-1, the input sensor 661-2, and the digitizer 661-3 may be formed to be integrated into one sensing panel through the same process. When being integrated into one sensing panel, the sensing panel may be placed between the display panel 641 and a window placed on the upper side of the display panel 641. According to some embodiments, the sensing panel may be placed on a window, and the location of the sensing panel is not particularly limited thereto.

At least one of the fingerprint sensor 661-1, the input sensor 661-2, or the digitizer 661-3 may be built into the display panel 641. That is, at least one of the fingerprint sensor 661-1, the input sensor 661-2, or the digitizer 661-3 may be simultaneously formed through a process of forming elements (e.g., a light emitting element, a transistor, or the like) included in the display panel 641.

Besides, the sensor module 661 may generate an electrical signal or a data value corresponding to the internal state or external state of the electronic device 601. For example, the sensor module 661 may further include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 662 may include one or more antennas to transmit or receive the signal or power to or from an external source. According to some embodiments, the communication module 673 may transmit or receive the signal to or from the external electronic device through the antenna suitable for a communication method. An antenna pattern of the antenna module 662 may be integrated into the input sensor 661-2 or one component (e.g., the display panel 641) of the display module 640.

The audio output module 663 may be a device for outputting an audio signal to the outside of the electronic device 601 and, for example, may include a speaker used for general purposes, such as multimedia playback or recording playback, and a receiver used only for receiving a call. According to some embodiments, the receiver may be implemented separately from the speaker or may be integrated with the speaker. A sound output pattern of the sound output module 663 may be integrated into the display module 640.

The camera module 671 may shoot a still image or a video image. According to some embodiments, the camera module 671 may include one or more lenses, an image sensor, or an image signal processor. The camera module 671 may further include an infrared camera capable of measuring the presence or absence of the user, a position of the user, a gaze of the user, or the like.

The light module 672 may provide light. The light module 672 may include a light emitting diode or a xenon lamp. The light module 672 may operate in conjunction with the camera module 671 or may operate independently from the camera module 1710.

The communication module 673 may support establishing a wired or wireless communication channel between the electronic device 601 and the external electronic device 602 and performing communication through the established communication channel. The communication module 673 may include one or all of wireless communication modules such as a cellular communication module, a short-range wireless communication module, or a global navigation satellite system (GNSS) communication module, or wired communication modules such as a local area network (LAN) communication module or a power line communication module. The communication module 673 may communicate with the external electronic device 602 through a short-range communication network such as Bluetooth, WiFi direct, or infrared data association (IrDA) or a long-range communication network such as a cellular network, Internet, or a computer network (e.g., the LAN or a wide area network (WAN)). The above-mentioned various communication modules 673 may be implemented into one chip or may be respectively implemented into separate chips.

The input module 630, the sensor module 661, the camera module 671, and the like may be utilized to control an operation of the display module 640 in conjunction with the processor 610.

The processor 610 outputs commands or data to the display module 640, the sound output module 663, the camera module 671, or the light module 672 based on input data received from the input module 630. For example, the processor 610 may generate image data in response to input data applied through a mouse, an active pen, or the like to output the generated image data to the display module 640 or may generate command data in response to the input data to output the generated command data to the camera module 671 or the light module 672. When no input data is received from the input module 630 during a specific period, the processor 610 may switch an operation mode of the electronic device 601 to a low-power mode or a sleep mode to reduce power consumed in the electronic device 601.

The processor 610 outputs commands or data to the display module 640, the sound output module 663, the camera module 671, or the light module 672 based on sensing data received from the sensor module 661. For example, the processor 610 may compare authentication data authorized by the fingerprint sensor 661-1 with the authentication data stored in the memory 620, and then may execute an application depending on the comparison result. The processor 610 may execute commands or may output corresponding image data to the display module 640 based on sensing data sensed by the input sensor 661-2 or the digitizer 661-3. When the sensor module 661 includes a temperature sensor, the processor 610 receives temperature data regarding the measured temperature from the sensor module 661 and may further perform luminance correction on image data based on the temperature data.

The processor 610 may receive measurement data regarding the presence or absence of the user, the user's location, and the user's gaze from the camera module 671. The processor 610 may further perform luminance correction on the image data based on the measurement data. For example, the processor 610 that determines the presence or absence of the user through an input from the camera module 671 may output image data, of which the luminance is corrected, to the display module 640 through the data converting circuit 612-2 or the gamma correcting circuit 612-3.

Some of the components may be connected to each other through communication methods between peripheral devices, for example, a bus, a general purpose input/output (GPIO), a serial peripheral interface (SPI), a mobile industry processor interface (MIPI), or an ultra-path interconnect (UPI) link and may exchange a signal (e.g., commands or data) between each other. The processor 610 may communicate with the display module 640 through a mutually promised interface, and for example, may use any one of the above-described communication methods, and the present disclosure is not limited to the above-described communication methods.

The electronic device 601 according to various embodiments disclosed in the specification may be implemented with various types of devices. The electronic device 601 may include, for example, at least one of a portable communication device (e.g., a smart phone), a computer device, a portable multimedia device, a portable medical device, a camera, a wearable device, or a home appliance. The electronic device 601 according to some embodiments of this specification may not be limited to the above-described devices.

Although aspects of some embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the disclosed subject matter should not be limited to any single embodiment described herein, and the scope of the present inventive concept shall be determined according to the appended claims, and their equivalents.

What is claimed is:

1. A display device comprising:
a display module;
a support plate under the display module and comprising a first support plate, a second support plate, and a folding plate between the first and second support plates, the folding plate being provided with openings defined therethrough and the first support plate, the second support plate, and the folding plate being arranged in a first direction;
a first wing plate under the folding plate;
a second wing plate under the folding plate and spaced apart from the first wing plate in the first direction;
a center plate between the first and second wing plates;
a folding supporter between the center plate and the folding plate; and
a cover layer between the folding supporter and the folding plate.

2. The display device of claim 1, wherein the folding supporter overlaps the openings in a plan view.

3. The display device of claim 1, wherein the cover layer covers the openings.

4. The display device of claim 3, wherein a width of the folding supporter is smaller than a width of the cover layer in the first direction.

5. The display device of claim 4, wherein the folding supporter overlaps a center of the cover layer.

6. The display device of claim 4, wherein an upper surface of the folding supporter is higher than lower ends of both sides of the cover layer, and a portion of the cover layer, which overlaps the folding supporter, protrudes upward by a predetermined height due to the folding supporter.

7. The display device of claim 5, wherein a distance between an upper end of both sides of the cover layer, which are opposite to each other in the first direction, and an uppermost end of an upper surface of the cover layer is within a range from 0 micrometers to 50 micrometers.

8. The display device of claim 3, wherein the folding supporter contacts a lower surface of the cover layer.

9. The display device of claim 1, further comprising:
a first single-sided tape attached to an upper surface of the first wing plate; and
a second single-sided tape attached to an upper surface of the second wing plate.

10. The display device of claim 1, further comprising a center single-sided tape attached to an upper surface of the center plate.

11. The display device of claim 10, wherein the folding supporter is on the center single-sided tape.

12. The display device of claim 10, wherein the folding supporter is attached to the center single-sided tape.

13. The display device of claim 1, wherein the folding plate comprises:
a curved portion through which the openings are defined;
a first reverse curvature portion between the first support plate and the curved portion;
a second reverse curvature portion between the second support plate and the curved portion;
a first extension portion between the curved portion and the first reverse curvature portion; and
a second extension portion between the curved portion and the second reverse curvature portion, the first wing plate is under the first extension portion, the second wing plate is under the second extension portion, and the center plate is under the curved portion.

14. The display device of claim 1, further comprising:
a first flat plate under the first support plate; and
a second flat plate under the second support plate.

15. The display device of claim 1, further comprising a metal sheet between the folding plate and the first and second wing plates and between the center plate and the folding plate.

16. The display device of claim 1, further comprising a plurality of dummy folding supporters between the folding plate and the first and second wing plates.

17. A display device comprising:
a display module;
a support plate under the display module and comprising a first support plate, a second support plate, and a folding plate between the first and second support plates, the folding plate being provided with openings defined therethrough and the first support plate, the second support plate, and the folding plate being arranged in a first direction;
a first wing plate under the folding plate;
a second wing plate under the folding plate and spaced apart from the first wing plate in the first direction;
a first folding supporter between the first wing plate and the folding plate; and
a second folding supporter between the second wing plate and the folding plate.

18. The display device of claim 17, further comprising a digitizer between the support plate and the first and second folding supporters.

19. The display device of claim 17, further comprising a metal sheet between the first and second wing plates and the first and second folding supporters.

20. An electronic device comprising:
a display device configured to display an image and comprising:
a display module;
a support plate under the display module and comprising a first support plate, a second support plate, and a folding plate between the first and second support plates, the folding plate being provided with openings defined therethrough and the first support plate, the second support plate, and the folding plate being arranged in a first direction;
a first wing plate under the folding plate;
a second wing plate under the folding plate and spaced apart from the first wing plate in the first direction;
a center plate between the first and second wing plates;
a folding supporter between the center plate and the folding plate; and
a cover layer between the folding supporter and the folding plate.
